(19) United States
(12) Patent Application Publication
(10) Pub. No.: US 2026/0038589 A1
(43) Pub. Date: Feb. 5, 2026

(54) SINGLE COMMAND SHADOW PROGRAMMING

(71) Applicant: Micron Technology, Inc., Boise, ID (US)

(72) Inventors: Dong Kyo Shim, Milpitas, CA (US); Taehyun Kim, San Jose, CA (US); Jisuk Kim, San Jose, CA (US); Kitae Park, San Jose, CA (US); Erwin E. Yu, San Jose, CA (US)

(73) Assignee: Micron Technology, Inc., Boise, ID (US)

(21) Appl. No.: 19/283,136

(22) Filed: Jul. 28, 2025

Related U.S. Application Data
(60) Provisional application No. 63/678,030, filed on Jul. 31, 2024.

(51) Int. Cl. G11C 11/56; G11C 16/10

(52) U.S. Cl. CPC G11C 11/5628; G11C 11/5671; G11C 16/10

(57) ABSTRACT

Methods, systems, and devices for techniques for single command shadow programming are described herein. A one-pass programming operation is performed by programming lower page data of an (N+1)-th program loop word line to memory cells of the memory array. Lower page data of an N-th program loop word line is read from the memory cells, and higher page data of the N-th program loop word line is programmed to the memory cells.

### CROSS-REFERENCE TO RELATED APPLICATION

This application claims priority to U.S. Provisional Application No. 63/678,030, filed on Jul. 31, 2024, entitled “SINGLE COMMAND SHADOW PROGRAMMING,” the content of which is incorporated by reference in its entirety for all purposes.

### TECHNICAL FIELD

This disclosure relates to one or more systems for memory, including programming techniques that account for a reduction in tier pitch between word lines in memory devices.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic “1” or a logic “0”. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information (e.g., obsolete information) can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A and 1B illustrate an example of a host system and a memory system that support techniques for word line group dependent read recovery period ramp-down in accordance with examples as disclosed herein.

FIG. 1C is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 depicts an example programming order of sub-blocks in a memory array during a conventional one-pass program operation.

FIG. 5 depicts an example programming order of sub-blocks in a memory array during a single command shadow programming operation in accordance with examples as disclosed herein.

FIG. 6 is a diagram showing example operations including a one-pass program and a single command shadow program operation of the memory device in accordance with examples as disclosed herein.

FIG. 7 is a diagram showing gray code for select data word lines of a memory device during example operations including a single command shadow program operation of the memory device in accordance with examples as disclosed herein.

FIG. 8 is an example diagram showing a threshold voltage distribution for memory devices during example operations including a single command shadow program operation of the memory device in accordance with examples as disclosed herein.

FIG. 9 is an example diagram showing threshold voltage distributions on select data word lines of a memory device during example operations including a single command shadow program operation of the memory device in accordance with examples as disclosed herein.

FIG. 10A-C are example diagrams showing threshold voltage distributions on select data word lines of a memory device during example operations including a single command shadow program operation of the memory device in accordance with examples as disclosed herein.

FIG. 11 is a graph showing different curves that represent a program time comparison of during example operations including a single command shadow program operation of the memory device in accordance with examples as disclosed herein.

FIG. 12 is a flow diagram of an example method to perform a single command shadow program operation, in accordance with examples as disclosed herein.

### DETAILED DESCRIPTION

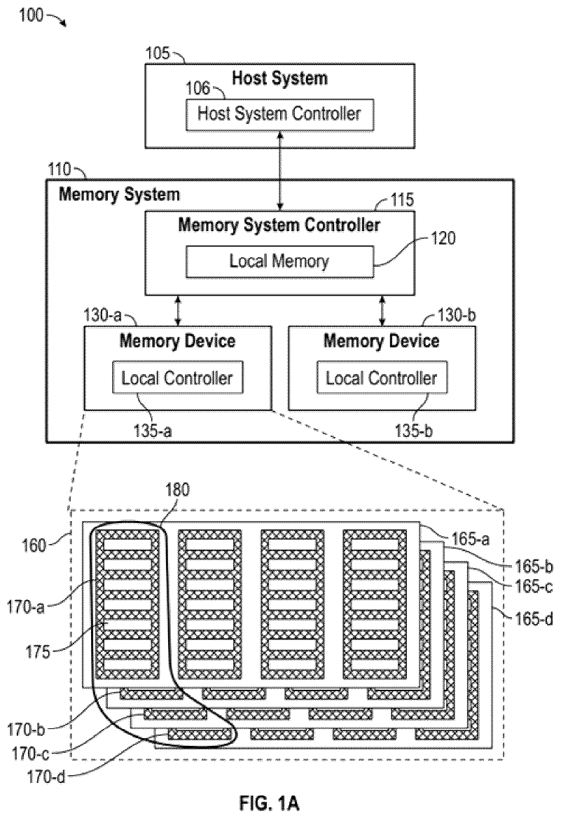

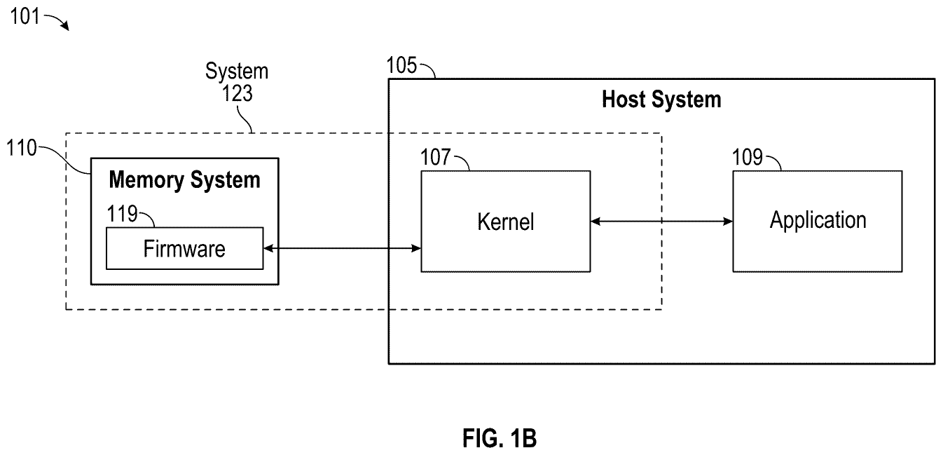

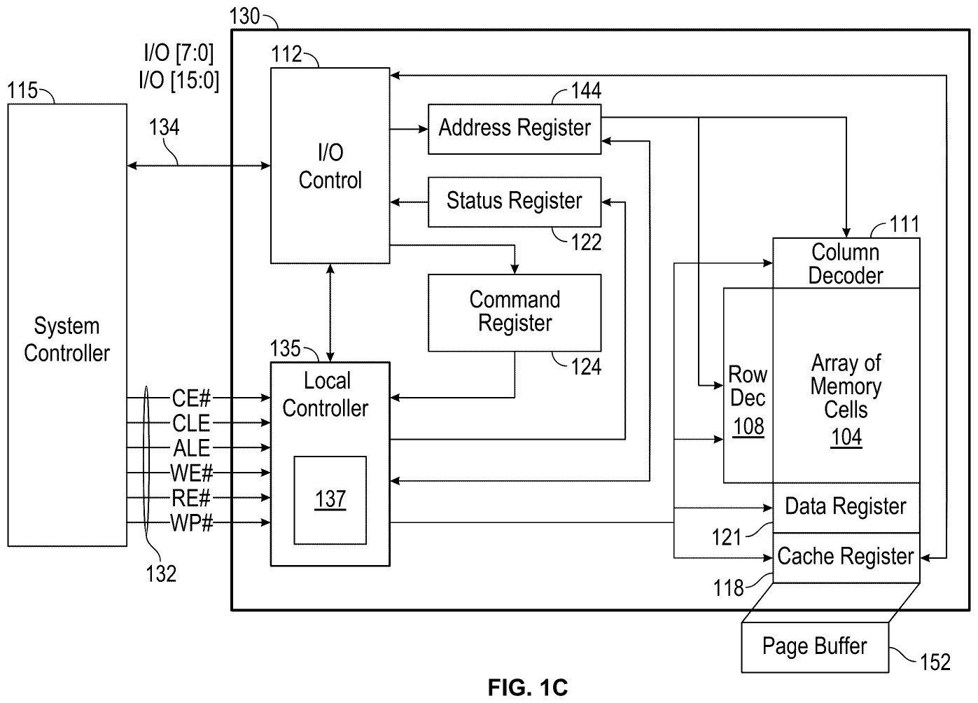

A host system may utilize a memory system that includes one or more components (e.g., memory devices that store data). The host system may provide data to be stored at the memory system and may request data to be retrieved from the memory system. Examples of a memory system are described below in connection with FIGS. 1A-C. The memory system may include high density non-volatile memory devices where retention of data is desired when power is not being supplied to the memory device. One example of a non-volatile memory device is a NAND flash memory device (also referred to herein as a NAND memory device). Non-volatile memory devices, such as flash memory devices, are widely used in computers and many electronic items to store information. A non-volatile memory device is a package of one or more dies. Each die may be comprised of one or more planes. For some types of non-volatile memory devices (e.g., NAND memory devices), each plane consists of a set of physical blocks. Each block consists of a set of pages. Each page consists of a group of memory cells (“cells”). The cells are electronic circuits that store information. Depending on the cell type, the cell may store one or more bits of binary information, and have various logic states related to the number of bits stored. A logic state may be represented by binary values, such as “0” and “1,” or a combination of such values.

A memory device may include a plurality of bits arranged in a two-dimensional grid. Memory cells are formed onto a silicon wafer in an array of columns (hereinafter also referred to as bit lines) and rows (hereinafter also referred to as word lines). A word line may refer to one or more rows of memory cells of a memory device that are used with one or more bit lines to generate an address for each memory cell. The intersections of the bit lines and word lines constitute the addresses of the memory cells. Hereinafter, a block or sub-block refers to a cell of a memory device for storing data, and may include a group of memory cells, a group of word lines, a word line, or a single memory cell. One or more blocks or sub-blocks may be combined to form planes of the memory device in order to allow concurrent operations to occur on each plane. A memory device may include circuitry that performs concurrent memory page accesses to two or more memory planes. For example, a memory device may include respective access line driver circuitry and power supply circuitry for each plane of the memory device to facilitate concurrent access to pages of two or more memory planes including different page types. A block or sub-block of memory in a flash memory device may comprise a grid of memory cells connected by word lines and bit lines such that data may be programmed or read from the flash memory device page-by-page.

For a variety of applications, the microelectronics industry has been incentivized to increase the memory density (e.g., the number of memory cells per memory die) of memory devices, such as non-volatile memory devices. One way of increasing memory density in non-volatile memory devices is to utilize vertical memory array (also referred to as a “three-dimensional (3D) memory array”) architectures. Whereas in a single-level cell (SLC) block of flash memory every word line contains one page, in a multi-level cell (MLC) block of flash memory every word line contains two pages. In a triple-level cell (TLC) block of flash memory every word line contains three pages, and in a quad-level cell (QLC) of flash memory every word line contains four pages. In some cases, pages within a word line can be further interleaved such that each word line may contain additional pages. In each case, such a memory device comprises access lines to access the memory cells during a memory operation (e.g., read, write, or erase operation). The memory device also comprises data lines to carry information (e.g., in the form of signals) to be stored in or read from the memory cells.

A conventional vertical memory array includes vertical memory strings extending through openings in a stack of “tiers” of conductive structures (e.g., word lines) and dielectric materials at each junction of the vertical memory strings and the conductive structures. Such a configuration permits a greater number of switching devices (e.g., transistors) to be located in a unit of die area (i.e., the length and width of active surface consumed) by building the array upwards (e.g., longitudinally, vertically) on a die, as compared to structures with conventional planar (e.g., two-dimensional) arrangements of transistors. Conventional vertical memory arrays further include electrical connections between the conductive structures and access lines (e.g., the word lines) so that memory cells in the vertical memory array can be uniquely selected for writing, reading, or erasing operations. One method of forming such an electrical connection includes forming so-called at least one “staircase” (or “stair step”) structure at edges (e.g., horizontal ends) of the tiers of conductive structures. The staircase structure includes individual “steps” providing contact regions of the conductive structures upon which conductive contact structures can be positioned to provide electrical access to the conductive structures. A “tier pitch”, as used herein the context of a memory device, means and includes a distance between a feature of a tier and a similar, corresponding feature of an adjacent tier. The terms “tier pitch” and “tier thickness” may be used interchangeably herein. As memory device tier pitch decreases, it becomes difficult to meet various high-reliability and high-performance standards required for industrial applications, e.g., in data center or enterprise applications.

Current reprogramming methods are proving to be increasingly inadequate for a new generation of reduced ter pitch triple-level cell (TLC) or quad-level cell (QLC) memory arrays, and can lead to significantly lower performance for demanding applications (e.g., high reliability/performance data center and enterprise applications. Therefore, a new programming algorithm suitable for high reliability/performance standard applications is needed. Particularly, it would be advantageous for a proposed new TLC or QLC shadow program algorithm, i.e., a program/write command for a cell or cells having the same word line biases or connection lines based on the requirement (a single command) of a host, to include one or more of the following attributes: (a) be readable after the program is performed (e.g., as is the case for a conventional TLC or QLC one-pass program); (b) not require a write buffer larger than a conventional one-pass program write buffer: (c) have an improved read window budget (i.e., the minimum window that the process must be able to sustain in order to have a reliable reading) with a same program time period t_{PROG} as a one-pass program; and have a same input/output efficiency as a conventional one-pass program.

Aspects of the present disclosure address the above and other deficiencies by implementing techniques for single command shadow programming. The various techniques may be implemented, for example, by a memory device comprising a memory array and control logic (e.g., a controller) coupled with the memory array, where the control logic is configured to perform the various operations.

In accordance with examples as disclosed herein, single command shadow programming comprises a method for programming multiple-level memory cells of a memory array in a one-pass programming operation. The one-pass programming operation may be carried out by a single programming command, and the multiple-level memory cells may be triple level memory cells or quad level memory cells. In the one-pass programming operation, lower page data of an (N+1)-th program loop word line is programmed to memory cells of the memory array. Lower page data of an N-th program loop word line is read from the memory cells, and lower page data and higher page data of the N-th program loop word line is programmed to the memory cells. Programming the higher page data may comprise programming upper page data and extra page data to the memory cells.

In some examples, a read level offset voltage is determined based on a program loop count threshold, and the lower page data of the N-th program loop word line is read from the memory cells based on the read level offset voltage.

In some examples, the one-pass programming operation may comprise a dual pulse programming operation, and the one-pass programming operation may be suspended for a time interval to read the lower page data of the N-th program loop word line from the memory cells.

In some examples, the one-pass programming operation may comprise reading the lower page data of the N-th program loop word line from the memory cells using a first read level offset voltage prior to a program loop count threshold and reading the lower page data of the N-th program loop word line from the memory cells using a second read level offset voltage after the program loop count threshold. A threshold voltage for programming the lower page data of the (N+1)-th program loop word line to the memory cells may be lower than a read-level threshold voltage after the program loop count threshold. In some examples, the program loop count threshold may be at least four program loops.

In accordance with examples as disclosed herein, a memory device comprises a memory array comprising multiple-level memory cells; and a controller, coupled with the memory array. The controller is configured to program the multiple-level memory cells via a one-pass programming operation. In the one-pass programming operation, lower page data of an (N+1)-th program loop word line is programmed to memory cells of the memory array. Lower page data of an N-th program loop word line is read from the memory cells, and lower page data and higher page data of the N-th program loop word line is programmed to the memory cells.

According to examples as disclosed herein, the single command shadow programming described herein may be implemented with any suitable memory device architecture. In one embodiment, the one-pass programming operation described herein may be implemented within a non-volatile memory device implementing 3D NAND flash technology.

Advantages of the present disclosure include, but are not limited to, more efficient programming of non-volatile memory devices (e.g., TLC and QLC memory devices that include NAND flash memory), and overall improved non-volatile memory device reliability and performance over conventional one-pass programming methods.

FIG. 1A illustrates an example of a system 100 that supports techniques for word line group dependent read recovery period ramp-down in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

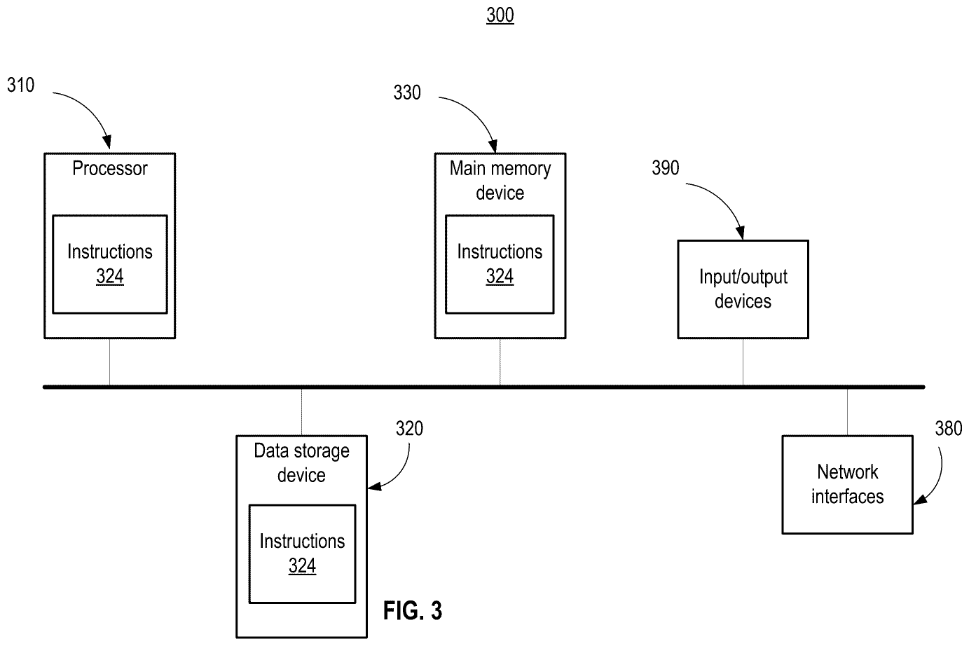

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a memory system controller 115 of memory system 110. In some examples, host system 105 may be coupled with memory system 110 (e.g., host system controller 106 may be coupled with memory system controller 115) via a respective physical host interface for each memory device 130 included in the memory system 110, or via a respective physical host interface for each type of memory device 130 included in memory system 110.

Memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

Memory system controller 115 may be coupled with and communicate with host system 105 (e.g., via the physical host interface) and may be an example of a controller or control component configured to cause memory system 110 to perform various operations in accordance with examples as described herein. Memory system controller 115 may also be coupled with and communicate with memory devices 130 to perform operations such as reading data, writing data, erasing data, or refreshing data at a memory device 130—among other such operations-which may generically be referred to as access operations. In some cases, memory system controller 115 may receive commands from the host system 105 and communicate with one or more memory devices 130 to execute such commands (e.g., at memory arrays within the one or more memory devices 130). For example, memory system controller 115 may receive commands or operations from host system 105 and may convert the commands or operations into instructions or appropriate commands to achieve the desired access of memory devices 130. In some cases, memory system controller 115 may exchange data with host system 105 and with one or more memory devices 130 (e.g., in response to or otherwise in association with commands from host system 105). For example, memory system controller 115 may convert responses (e.g., data packets or other signals) associated with the memory devices 130 into corresponding signals for the host system 105.

Memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to memory system controller 115. Memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

Memory system controller 115 may also include a local memory 120. In some cases, local memory 120 may include read-only memory (ROM) or other memory that may store operating code (e.g., executable instructions) executable by memory system controller 115 to perform functions ascribed herein to memory system controller 115. In some cases, local memory 120 may additionally, or alternatively, include static random access memory (SRAM) or other memory that may be used by memory system controller 115 for internal storage or calculations, for example, related to the functions ascribed herein to memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1A, a memory device 130-a may include a local controller 135-a and a memory device 130-b may include a local controller 135-b. In this disclosure, a memory system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, a memory system 110 may compress an L2P mapping to expand the quantity of physical addresses mapped by the L2P mapping. For example, if a set of consecutive entries of an uncompressed L2P mapping includes consecutive physical addresses, memory system 110 may compress the consecutive entries into a single entry which includes a starting physical address of the consecutive physical addresses. Additionally, memory system 110 may include an indication of a starting logical address corresponding to the starting physical address in the compressed entry. To identify a physical address within the compressed entry, memory system 110 may determine an offset between a logical address corresponding to the physical address (e.g., a logical address included in a read command for data stored at the physical address) and the starting physical address using the indication, and may apply the offset to the starting physical address to determine the physical address. Compressing the L2P mapping may allow the L2P mapping to cover an expanded range of physical address space without increasing the size of the L2P mapping.

FIG. 1B illustrates an example of a system diagram 101 that illustrates communication between host system 105 and memory system 110 via using a kernel and firmware, in accordance with examples as disclosed herein. System diagram 101 may include a memory system 110, a kernel 107, and an application 109. The memory system 110 may include a firmware 119. Firmware 119 may be implemented by a controller and/or other circuitry of the memory system (e.g., memory system controller 115 and/or local controllers 135 shown in FIG. 1A). In some examples, a system 123 as described herein may include memory system 110 and kernel 107. Additionally, a host system 105 may include kernel 107 and the application 109.

As described above, memory system 110 may include multiple memory devices, including non-volatile memory devices and volatile memory devices (e.g., local memory 120), configured to store and retrieve data. Firmware 119 may refer to software stored within a memory array within memory system 110 (e.g., a non-volatile memory device within the memory system 110) and/or a local memory 120 as shown in FIG. 1A. Firmware 119 may provide low-level control functions for the memory system 110. For example, firmware 119 may function as an interface between the memory system 110 and other components of the system 123, and host system 105 may issue access operations to memory system 110 by interfacing with firmware 119. In some examples, firmware 119 may be or be included within or implemented by a memory system controller 115, as described herein with reference to FIG. 1A. In some examples, memory system 110 may store a logical-to-physical mapping that maps logical addresses to physical addresses within a non-volatile memory device (e.g., in a logical-to-physical table). To perform a memory access operation, memory system 110 may move a portion of the logical-to-physical mapping corresponding to one or more logical addresses (e.g., indicated by kernel 107) from the non-volatile memory device to a volatile memory device.

Kernel 107 may function as an interface between host system 105 and components associated with host system 105, such as an operating system of host system 105. Additionally, kernel 107 may perform resource allocation and file management, among other operations, for host system 105. For example, an application 109 running within host system 105 may access information stored within memory system 110 by issuing commands to kernel 107, which may indicate files to be accessed. Kernel 107 may store mapping information associated with the files. For example, a file may be associated with a file name, and may correspond to a range of logical block addresses. Kernel 107 may store mapping information (e.g., a mapping table) that may track logical block addresses corresponding to files of host system 105. In some examples, application 109 may issue an access command to kernel 107 indicating a file name, and offset, and a length associated with a file to be accessed, and kernel 107 may retrieve a one or more logical block addresses corresponding to the file to be accessed. Kernel 107 may then communicate with firmware 119 to indicate the one or more logical block addresses to memory system 110, and memory system 110 may perform an access operation based on the one or more logical block addresses. Memory system 110 may communicate the accessed information to kernel 107 (e.g., via the firmware 119).

In some examples, kernel 107 may communicate with to firmware 119 using information units (e.g., UFS protocol information units (UPIUs)). For example, kernel 107 may issue or receive commands, responses, data, or other information via information units exchanged with the firmware 119. An information unit may refer to a data packet that may contain a header segment and one or more transaction specific fields. In some examples, an information unit may additionally include one or more extended header segments, one or more data segments, or a combination thereof. The header segments of an information unit may indicate information associated with a destination for the information unit, a source of the information unit, a function request, whether additional data or parameters are to be transmitted, whether the additional data or parameters are included within the information unit or to be sent in a following information unit, or any combination thereof. The transaction specific fields may be used for additional fields depending on the operation associated with the information unit. The data segments may be used to include data to be transferred from a device to another.

In some examples, a command information unit (e.g., a command UPIU) may be an example of an information unit associated with the transmission of a command (e.g., an SCSI command) and may indicate a device to perform some operation indicated by the command information unit. For example, the command information unit may include a block descriptor (e.g., a command descriptor block) which may indicate information related to the operation indicated by the command information unit. In some examples, kernel 107 may transfer a command information unit to memory system 110 to indicate memory system 110 of an operation to be performed by memory system 110.

In some examples, to perform an access operation, memory system 110 may load a L2P mapping associated with information to be accessed. For example, memory system 110 may transfer a portion of a logical-to-physical mapping associated with the information to be accessed from a non-volatile memory device of memory system 110 (e.g., NAND memory) to a volatile memory device (e.g., an SRAM) of the memory system 110. In another example, host system 105 may notify memory system 110 of a logical block address range corresponding to an upcoming access operation (e.g., prior to issuing an access command). Memory system 110 may use the logical block address range to load (e.g., pre-load, pre-fetch) an associated portion of a L2P mapping (e.g., from a non-volatile memory device to a volatile memory device) prior to receiving an access command that indicates memory system 110 to perform the access operation. Accordingly, after host system 105 issues the access command, memory system 110 may issue a response to host system 105 faster as memory system 110 has already loaded relevant portions of the L2P mapping associated with the access operation.

The above description of the system diagram 101 are illustrative examples of communication between host system 105 and memory system 110 by using a kernel 107, application 109, and firmware 119. It is understood that additional ways of communication, including function calls, commands, responses, messages, etc. can be implemented using host system 105 and memory system 110, and/or additional systems or components.

FIG. 1C is a simplified block diagram of a memory device 130 in communication with a memory system controller 115 of a memory system (e.g., the memory system 110 of FIGS. 1A and 1B), according to an embodiment. As shown in FIG. 1C and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1C) of at least a portion of the array of memory cells 104 are capable of being programmed to one of at least two target data states for storing any number of bits of information.

With continued reference to FIG. 1C, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external memory system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the memory system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to memory system controller 115.

As shown in FIG. 1C, memory device 130 receives various control signals via local controller 135 from memory system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the memory system controller 115 over a multiplexed input/output (I/O) bus 134 and outputs data to the memory system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1C has been simplified. It should be recognized that the functionality of the various block components described with reference to FIG. 1C may not necessarily be segregated to distinct components or component portions of an integrated circuit device. For example, a single component or component portion of an integrated circuit device could be adapted to perform the functionality of more than one block component of FIG. 1C. Alternatively, one or more components or component portions of an integrated circuit device could be combined to perform the functionality of a single block component of FIG. 1C. Additionally, while specific I/O pins are described in accordance with popular conventions for receipt and output of the various signals, it is noted that other combinations or numbers of I/O pins (or other I/O node structures) can be used in the various embodiments.

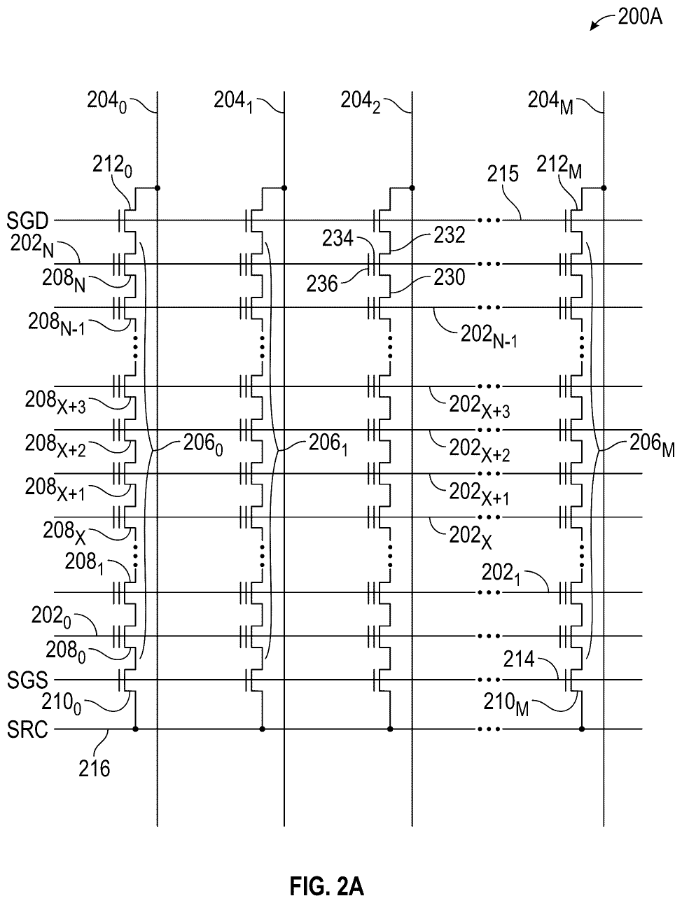

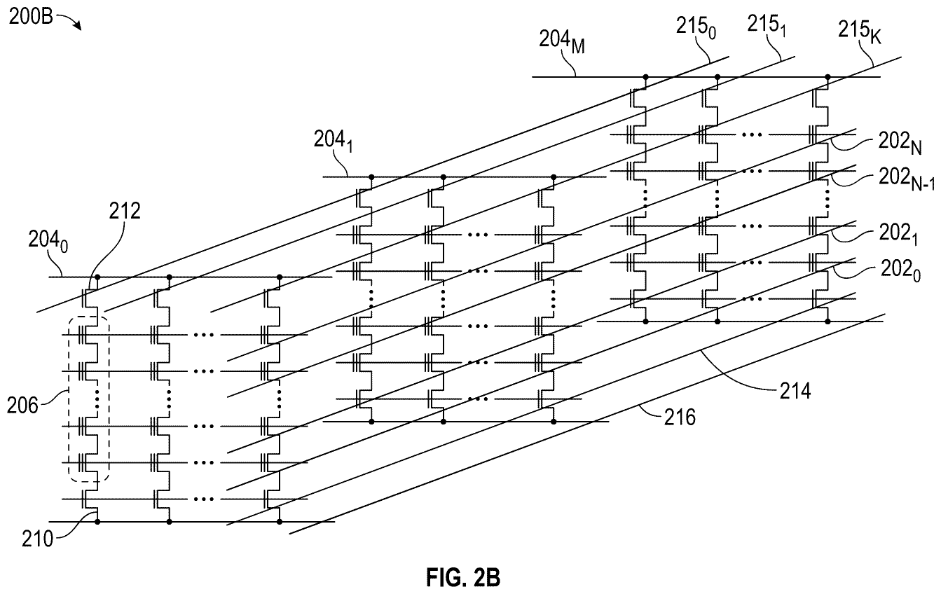

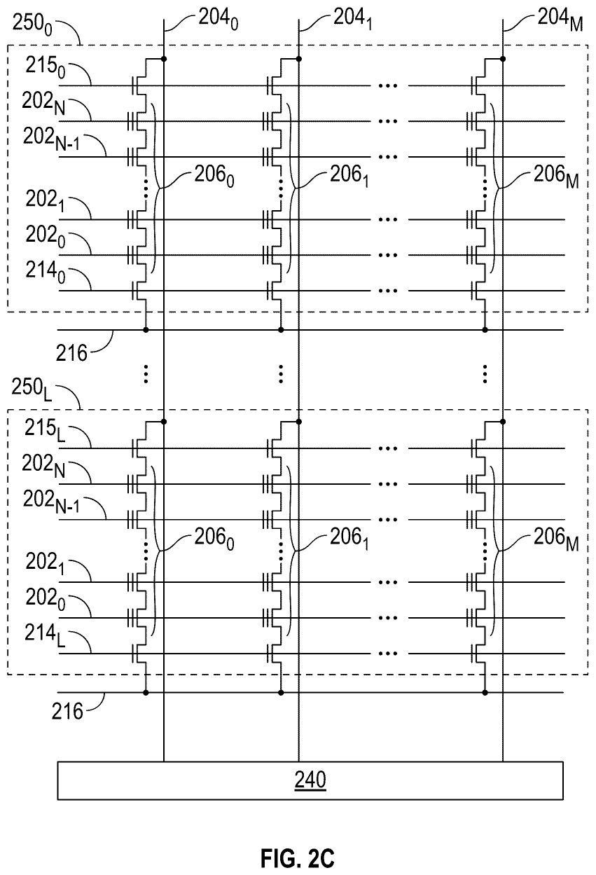

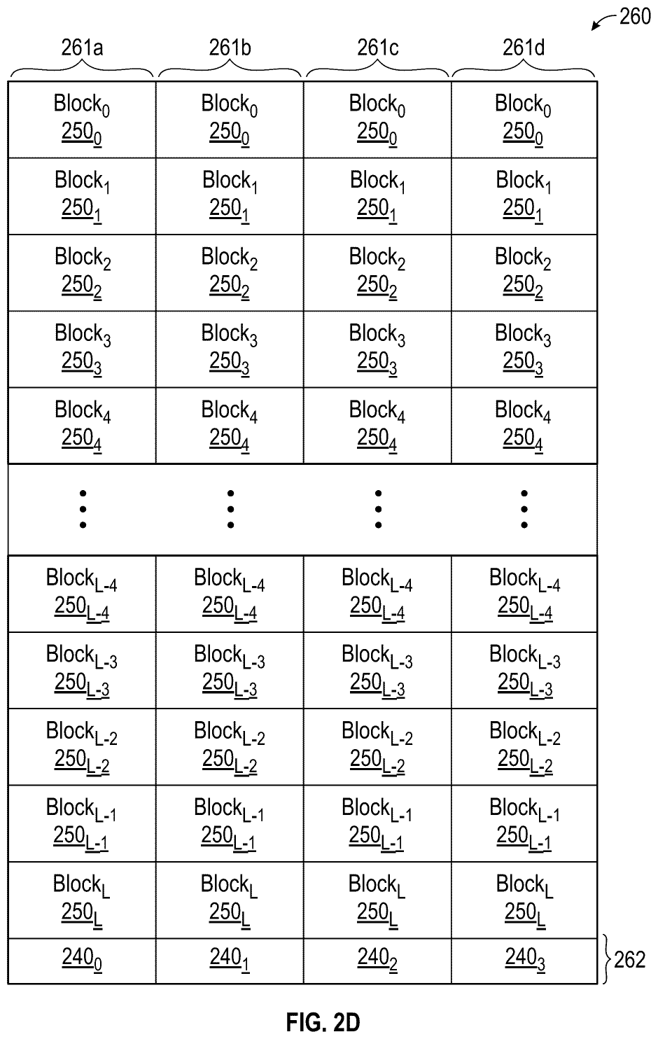

FIG. 2A-2B are example schematics of portions of an array of memory cells 200A, such as a NAND memory array. Array of memory cells 200A may be an example of memory array 104 of a memory device 130 as described with reference to FIG. 1C according to an embodiment. Memory array 200A includes access lines, such as word lines 2020 to 202x, and data lines, such as bit lines 2040 to 204M. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 2060 to 206M. Each NAND string 206 can be connected (e.g., selectively connected) to a common source (SRC) 216 and can include memory cells 2080 to 208x. The memory cells 208 can represent non-volatile memory cells for storage of data. The memory cells 208 of each NAND string 206 can be connected in series between a select gate 210 (e.g., a field-effect transistor), such as one of the select gates 2100 to 210M (e.g., that can be source select transistors, commonly referred to as select gate source), and a select gate 212 (e.g., a field-effect transistor), such as one of the select gates 2120 to 212M (e.g., that can be drain select transistors, commonly referred to as select gate drain). Select gates 2100 to 210M can be commonly connected to a select line 214, such as a source select line (SGS), and select gates 2120 to 212 can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 2080 of the corresponding NAND string 206. For example, the drain of select gate 2100 can be connected to memory cell 2080 of the corresponding NAND string 2060. Therefore, each select gate 210 can be configured to selectively connect a corresponding NAND string 206 to the common source 216. A control gate of each select gate 210 can be connected to select line 214.

The drain of each select gate 212 can be connected to bit line 204 for the corresponding NAND string 206. For example, the drain of select gate 2120 can be connected to the bit line 2040 for the corresponding NAND string 2060. The source of each select gate 212 can be connected to a memory cell 208x of the corresponding NAND string 206. For example, the source of select gate 2120 can be connected to memory cell 208x of the corresponding NAND string 2060. Therefore, each select gate 212 can be configured to selectively connect a corresponding NAND string 206 to the corresponding bit line 204. A control gate of each select gate 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202x and selectively connected to even bit lines 204 (e.g., bit lines 2040, 2042, 2044, etc.) can be one physical page of the memory cells 208 (e.g., even memory cells) while memory cells 208 commonly connected to word line 202x and selectively connected to odd bit lines 204 (e.g., bit lines 2041, 2043, 2045, etc.) can be another physical page of the memory cells 208 (e.g., odd memory cells).

Although bit lines 2043-2045 are not explicitly depicted in FIG. 2A, it is apparent from the figure that the bit lines 204 of the array of memory cells 200A can be numbered consecutively from bit line 2040 to bit line 204M. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 2020-202x (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 2040-204 by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 2150-215K to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

As described above, memory cells can be grouped into memory blocks. FIG. 2C depicts groupings of NAND strings 206 into blocks of memory cells 250, e.g., blocks of memory cells 2500-2501. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 2150. The common source 216 for the block of memory cells 2500 can be a same source as the source 216 for the block of memory cells 250L. For example, each block of memory cells 2500-250L, can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 2500-250L.

The bit lines 2040-204M can be connected (e.g., selectively connected) to a buffer portion 240, which can be a portion of the page buffer 152 of the memory device 130. The buffer portion 240 can correspond to a memory plane (e.g., the set of blocks of memory cells 2500-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130 described with reference to FIG. 1C. The array of memory cells 260 is depicted as having four memory planes 261 (e.g., memory planes 261a-261d). Each of the memory planes 261 can correspond to planes 165 depicted in FIG. 1A. Each memory plane 261 can be in communication with a respective buffer portion 240, which can collectively form a page buffer 262. Page buffer 262 may be used to implement page buffer 152 shown in FIG. 1C. While four memory planes 261 are depicted, other numbers of memory planes 261 can be commonly in communication with a page buffer 262. Each memory plane 261 is depicted to include L+1 blocks of memory cells 250 (e.g., blocks of memory cells 2500-250L).

With continued reference to FIGS. 1C and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA) with an erase pulse while the select gates 2100 to 210M (SGS transistors) are turned on. Ramping to this high bias erase voltage, and the subsequent recovery from this voltage ramping, may take a significant amount of time. Concurrently, the erase operation manager 137 can cause the select gates 2120 to 212m (FIG. 2A) to be turned off to enable the drains of the select gates 2120 to 212m to float, which causes the bit lines 2040 to 204M to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 2080 to 208x to be erased, e.g., forces electrons to exit through a body of each memory cell and out the floating bit lines 2040 to 204M. In other embodiments, the reverse can be done so the select gates 2100 to 210M are turned off, causing the SRC line 216 to float while the voltage of the bit lines are ramped to Vera while the select gates 2120 to 212 are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1A-2D and 4-12, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system (e.g., host system 105 shown in FIG. 1A) that includes, is coupled to, or utilizes a memory system (e.g., memory system 110 of FIG. 1A). Apparatus 300 can be used to perform operations of a controller (e.g., to execute an operating system to perform operations corresponding to host system controller 106 and/or local controller 135 of FIG. 1A).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., host system controller 106 and/or local controller 135 of FIG. 1A). The computer program instructions 324 may be stored in data storage device 320, or other computer-readable medium, and loaded into main memory device 330 when execution of the computer program instructions is desired. For example, processor 310 may be used to implement one or more components and systems described herein, such as host system controller 106 and/or local controller 135 (shown in FIG. 1A). Thus, the method steps of at least some of FIGS. 1A-2D and 4-12 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1A-2D and 4-12. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using memory system 110 (FIG. 1A) described herein. In some examples, data storage device 320 and main memory device 330 may include one or more memory devices 130 (FIG. 1A).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

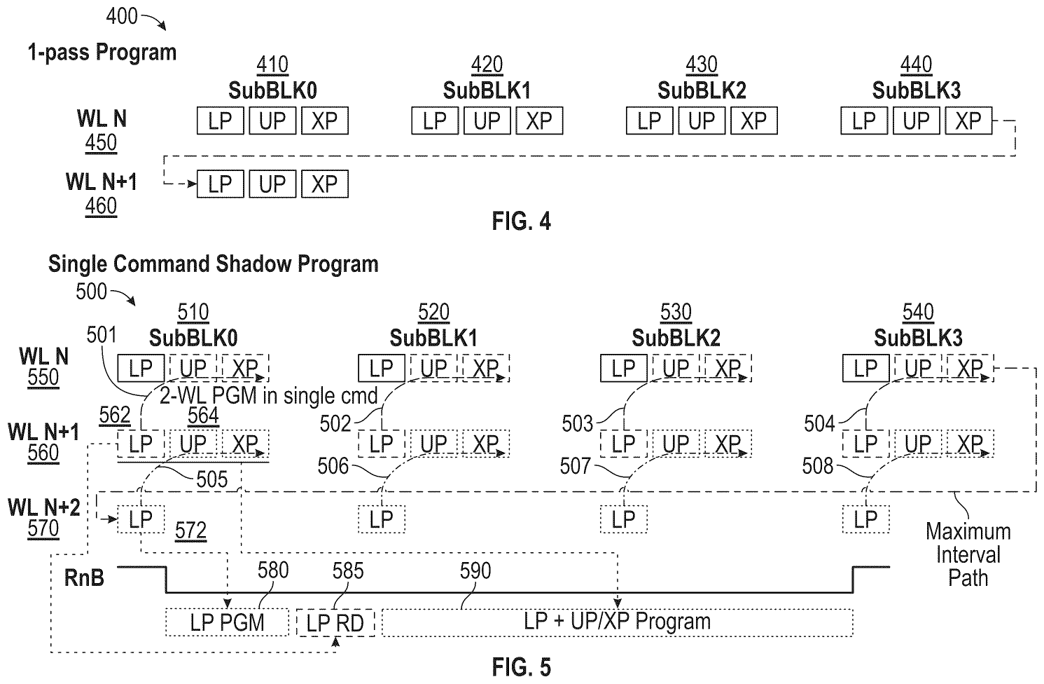

FIG. 4 depicts an example programming order of sub-blocks in a memory array during a conventional one-pass program operation. In the present example, the conventional one-pass program operation is described in the context of the memory array 400 configured for TLC operations. Thus, in this example, each sub-block includes three pages: LP. UP, and XP that are programed in order. But it should be recognized that for other examples, a one-pass program operation can similarly apply other multi-level cell operations (e.g., QLC, PLC, etc.) with a corresponding number of pages. For example, in the context of QLC one-pass programming, each sub-block includes four pages that are programmed in order.

As shown, a portion of a memory array 400 (e.g., similar to memory array 104 or 260) includes sub-blocks SubBLK0 410, SubBLK1 420, SubBLK2 430, SubBLK3 440 and data word lines WL N 450 and WL N+1 460 of a memory device during example operations including a one-pass program operation of the memory device. For example, the program order for word lines N 450 and N+1 460 is shown for a conventional one-pass operation for programming a memory device, e.g., a memory device comprising a triple-layer cell (TLC) NAND flash memory array. Sub-blocks SubBLK0 410, SubBLK1 420, SubBLK2 430, SubBLK3 440, each comprising segmented layers of the memory device, are shown. In each sub-block, the lower page (LP), upper page (UP), and extra page (XP) are programmed using the one-pass program before the LP, UP, and XP of the next sub-block. For example, the first SubBLK0 410 (LP. UP. XP) of WL N 450 is programmed during a first program time period, (prog. The second sub-block, SubBLK1 420, of WL N 450 is programmed during a second t_{prog}. The third sub-block. SubBLK2 430, of WL N 450 is programmed during a third t_{prog}, and the fourth sub-block, SubBLK3 440, of WL N 450 is programmed during a fourth tong. After SubBLK3 440 of WL N 450 is programmed, the one-pass program operation continues to a next word line, WL N+1 460, where each sub-block is programmed in sequential order. For example, the one-pass operation may continue by performing operations to program SubBLK0 410 (LP. UP, XP) of WL N+1 460 during a fifth program time period, t_{prog}.

FIG. 5 depicts an example programming order of sub-blocks in a memory array during a single command shadow programming operation in accordance with examples as disclosed herein. As shown, a portion of a memory array 500 (e.g., similar to memory array 104 or 260) includes sub-blocks SubBLK0 510, SubBLK1 520. SubBLK2 530, SubBLK3 540 and data word lines WL N 550, WL N+1 560 and WL N+2 570 of a memory device, e.g., comprising a triple-layer cell (TLC) NAND flash memory array.

In the present example, the single command shadow programming operation is described in the context of the memory array 500 configured with multiple-level memory cells, e.g., a TLC memory array. Thus, in this example, each sub-block includes three pages: LP, UP, and XP that are programed in accordance with the operation. But it should be recognized that for other examples, a single command shadow programming operation can similarly apply other multi-level cell operations (e.g., QLC, PLC, etc.) with a corresponding number of pages. For example, in the context of QLC single command shadow programming, each sub-block includes four pages that are programmed in accordance with the operation.

In the example of FIG. 5, a programming order of sub-blocks in memory array 500 during a single command shadow programming operation is shown as the programming operation progresses from an initial sub-block to subsequent sub-blocks (from SubBLK0 510 to SubBLK1 520 to SubBLK2 530 to SubBLK3 540) and from an initial WL to subsequent WLs (from WL N 550 to WL N+1 560 to WL N+2 570). The illustrated example operations follow the progression of single command shadow programming operations starting with the initial sub-block and WLs (SubBLK0 510, WL N 550 and WL N+1 560) programmed in a first one-pass single command shadow programming operation to subsequent sub-blocks and WLs programmed in subsequent single command shadow programming operations. It should be noted that portions of two WLs are programmed in a single pass.

Each programming operation is denoted in FIG. 5 by an arrow showing the pages of the two WLs that are programmed in a single operation. A total of eight single command shadow programming operations are shown in the example. In an embodiment, a controller (e.g., host system controller 106 and/or local controller 135 of FIG. 1A) may be configured to program the multiple-level memory cells (SubBLK0 510. SubBLK1 520, SubBLK2 530, SubBLK3 540) via a one-pass programming operation comprising operations to: program lower page data to memory cells along an (N+1)-th word line; read lower page data from memory cells along an N-th word line; and program higher page data to memory cells along the N-th word line. For example, in an initial single command shadow program during a first time period, t_{prog}, denoted by arrow 501. SubBLK0 510 lower page data is programmed to memory cells along an (N+1)-th word line in a single pass with higher page data to memory cells along the N-th word line. During a second time period, t_{prog}, denoted by arrow 502, SubBLK1 520 lower page data is programmed to memory cells along an (N+1)-th word line in a single pass with higher page data to memory cells along the N-th word line. During a third time period, t_{prog}, denoted by arrow 503, SubBLK2 530 lower page data is programmed to memory cells along an (N+1)-th word line in a single pass with higher page data to memory cells along the N-th word line. During a fourth time period, t_{prog}, denoted by arrow 504, SubBLK3 540 lower page data is programmed to memory cells along an (N+1)-th word line in a single pass with higher page data to memory cells along the N-th word line. During a fifth time period, t_{prog}, denoted by arrow 505, SubBLK0 510 lower page data is programmed to memory cells along an (N+2)-th word line in a single pass with higher page data to memory cells along the (N+1)-th word line. During a sixth time period, prog, denoted by arrow 506. SubBLK1 520 lower page data is programmed to memory cells along an (N+2)-th word line in a single pass with higher page data to memory cells along the (N+1)-th word line. During a seventh time period, t_{preg}, denoted by arrow 507, SubBLK2 530 lower page data is programmed to memory cells along an (N+2)-th word line in a single pass with higher page data to memory cells along the (N+1)-th word line, and during an eighth time period, t_{prog}, denoted by arrow 508. SubBLK3 540 lower page data is programmed to memory cells along an (N+2)-th word line in a single pass with higher page data to memory cells along the (N+1)-th word line.

In an embodiment, a one-pass single command shadow programming operation further comprises reading lower page data from memory cells along an N-th word line between programming lower page data to memory cells along an (N+1)-th word line and higher page data to memory cells along the N-th word line. These features of the operation improve performance over a conventional two-pass program (e.g., a one pass program per WL over two WLs) for a multiple-level (e.g., TLC, QLC, etc.) memory array for various reasons. For example, the operation can handle three pages of data for programming memory cells along two WLs in a single pass without requiring a write buffer larger than a conventional one-pass per WL program write buffer. The single command shadow program operation also lowers the possibly of error incurred due to charge loss. For example, charge loss occurring after a first write operation can cause errors when stored data is read for a second write operation. However, the single command shadow program operation mitigates this potential charge loss by separating the LP and UP/XP programming operations, e.g., by reading lower page data from memory cells along an N-th WL before programming upper page data to memory cells along an (N+1) WL.

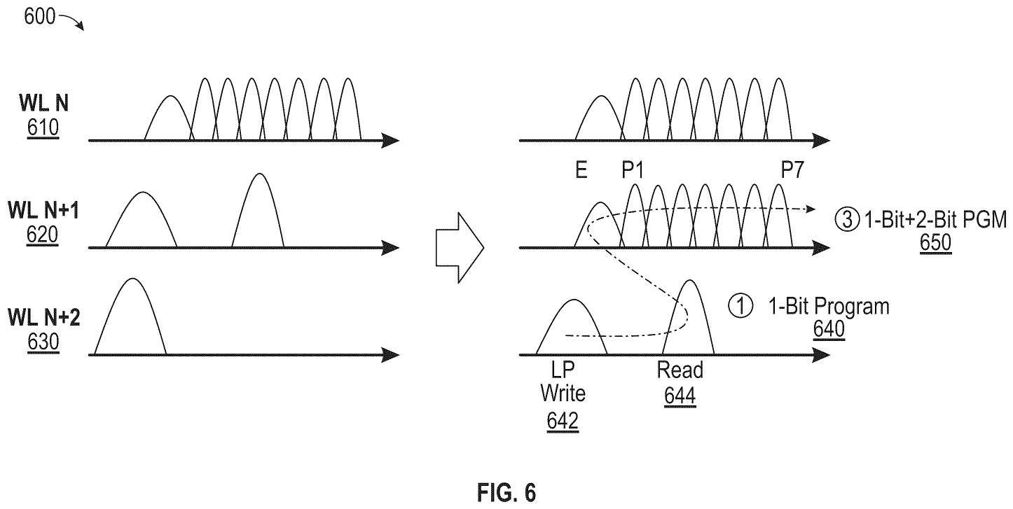

FIG. 6 is a diagram 600 showing example operations including a one-pass program and a single command shadow program operation of the memory device in accordance with examples as disclosed herein. In diagram 600, programming pulses are shown for physical word lines N 610. N+1 620, and N+2 630 for a single command shadow program operation of a memory device, e.g., comprising a triple-layer cell (TLC) NAND flash memory array. For example, for physical word lines N+1 620 and N+2 630 during a time period, t_{prog}, a one-bit program operation 640 is performed comprising a WL N+2 lower page write operation 642 and read operation 644. Next, a 1-bit+2-bit (LP+UP/XP) program operation 650 is performed for WL N+1 620 to code an erase state and program states P1-P7 for WL N+1 620.

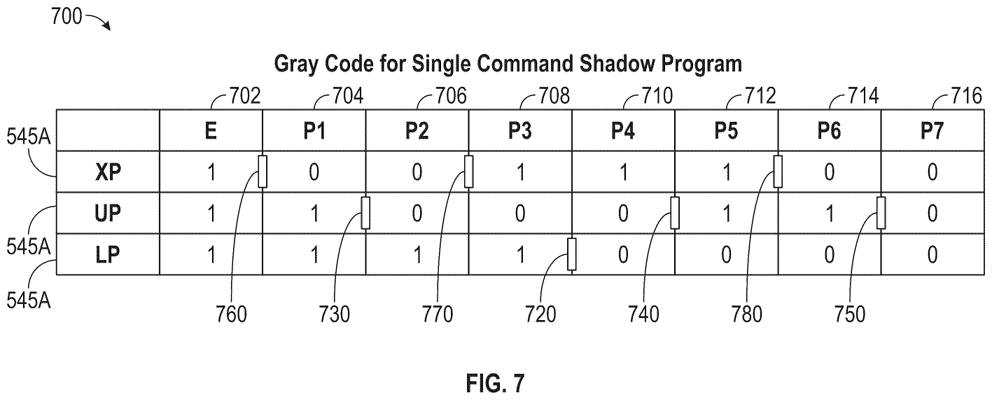

FIG. 7 is a diagram showing gray code 700 for select data word lines of a memory device during example operations including a single command shadow program operation of the memory device in accordance with examples as disclosed herein. In gray code 700, an erase state 702 and program states P1-P7 704-716 are shown for a single command shadow program operation, e.g., the 1-bit+2-bit (LP+UP/XP) program operation 650 performed for WL N+1 620 in FIG. 6 above. In an example, the single command shadow program operation requires one LP read 720 to determine which of the two possible states (“1” and “0”) is active. For the four possible states of the UP and XP in each of the two possible LP states (eight total UP/XP states), both the UP and XP each require three read operations, 730-750 and 760-780, respectively.

Referring back to FIG. 5, the SubBLK0 510 program operation denoted by arrow 505 is illustrated in FIG. 5 as a specific example.

In the program operation denoted by arrow 505, a controller (e.g., local controller 135 described with respect to FIG. 1C above) may be configured to program the multiple-level memory cells of SubBLK0 510 via a one-pass programming operation during a time period, tprog. The operations may comprise programming 580 lower page data 572, which has two possible states (“1” and “0”), to memory cells along WL N+2 570 (the controller gives data to a memory device).

Continuing to refer to FIG. 5, the controller may be further configured to read 585 lower page data 562 (having two possible states) from memory cells along WL N+1 560 (a different WL from WL. N+2) to reinstate or refresh previously programmed LP data of WL N+1 560 (e.g., the memory device gives data read from the memory cell to the controller). For example, after programming 580 lower page data 572 to memory cells along WL N+2, the WL N+1 LP data 562 is flushed from the controller's write buffer. Further, due to the current tier pitch challenges described above, a bias voltage of the WL N+2 LP 572 may be close enough to a bias voltage for the WL N+1 LP 562 for uncorrectable errors to occur when programming the WL N+1 LP 562. Thus, the LP read operation 585 is performed to retrieve/restore the WL N+1 LP data 562.

Continuing to refer to FIG. 5, the controller may be further configured to program 590 higher page (UP/XP) data to memory cells along WL N+1 560. After the restoration of the WI. N+1 LP data 562, the operation comprises programming (the controller gives data to the NAND memory device) the upper pages (e.g., UP/XP 564) in a one-bit+two-bit program having eight possible states. Therefore, pages in two WLs (N+2 and N+1) are programmed by a single command during a single t_{prog}.

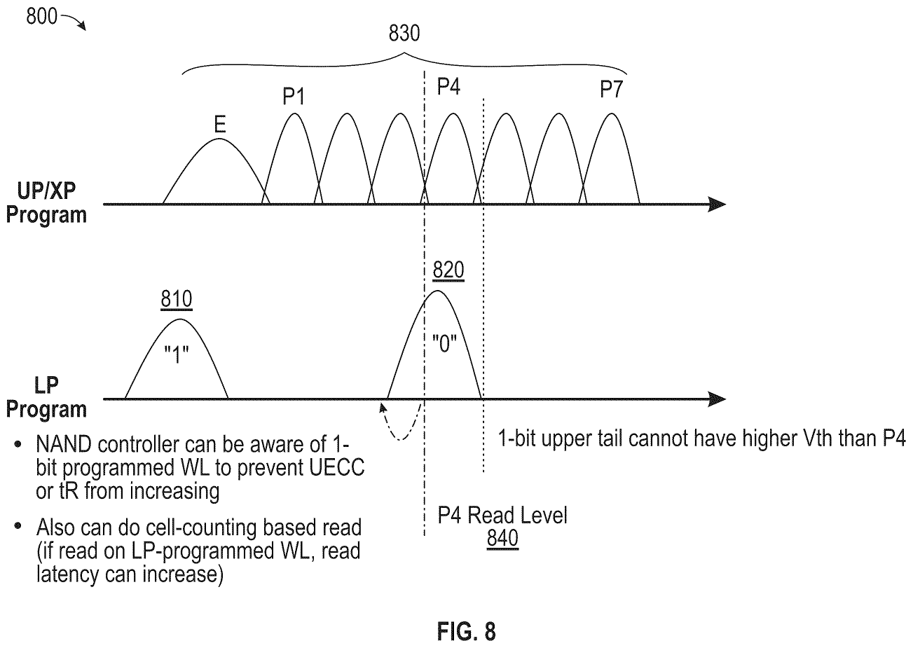

In some embodiments, a threshold voltage distribution used for programming 590 higher page data to memory cells along WL. N+1 560 can be determined based on the bias voltage for the WL N+1 LP 562, such that the WL N+1 LP 562 read level can be distinguished from a subsequent read level. FIG. 8 is a diagram 800 showing a threshold voltage distribution for memory devices along a data word line of a memory device during single command shadow program operations in accordance with examples as disclosed herein. In diagram 800, LP program pulses “1” 810 and “0” 820 and UP/XP program pulses E through P7 830 are shown. For example, a memory controller can be configured to obtain threshold voltages for the 1-bit programmed WL, e.g., LP program pulses “1” 810 and “0” 820, to prevent uncorrectable error correction (UECC) or read time, tr, from increasing. Moreover, the memory controller be configured to count the number of memory cells being programmed to prevent the 1-bit upper tail of LP program pulse “0” state 820 from having a higher threshold voltage, Vai, than a subsequent read voltage, the P4 read level (RP4) 840. For example, in a TLC scenario, the maximum LP read level should not be higher than the RP4 LP Program. The LP program Vth distribution is also the initial point to be written by the UP/XP program pulse, ‘0’ and should not be over programmed. Therefore, RP4 should be higher than the ‘0’ state of the LP Read 820.

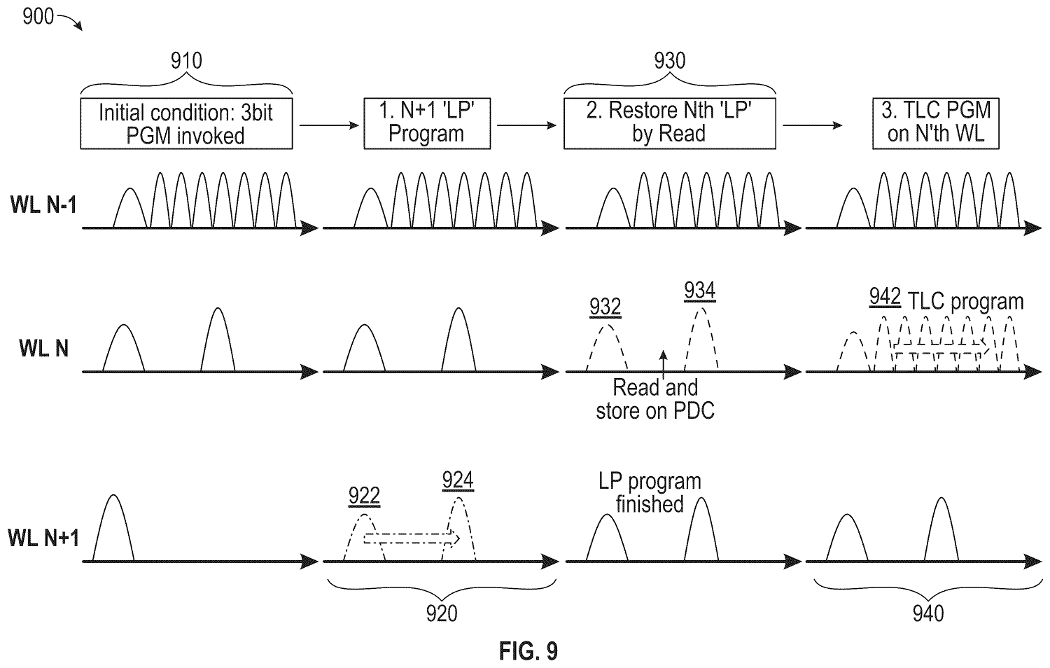

FIG. 9 is a diagram 900 showing threshold voltage distributions on select data word lines of a memory device during a single command shadow program operation in accordance with examples as disclosed herein.

In an initial condition 910, a three-bit single command shadow program is invoked.

The one-pass single command shadow program further comprises programming lower page data 920 to memory cell along an (N+1)-th word line to memory cells of the memory array. As shown, the threshold voltage distributions for the lower page data have two possible states 922 and 924 (representing a logical “0” and “1”).

Lower page data is read from memory cell along an N-th word line at 930. As described in FIG. 8 above, there is a gap between the one-pass 1-bit (LP) and 2-bit (LP+UP/XP) program operations that allows for the N-th LP data to be read and stored, e.g., on a Primary Data Cache (PDC), during the gap. The N-th LP read 930 restores the N-th LP data after the N+1-th LP program. As shown, the threshold voltage distributions for the lower page data read operation have two possible states 932 and 934 (representing a logical “0” and “1”). It should be noted that the LP read is overhead versus the typical one-pass program, but the overall single command shadow program time overhead is minimized in the finalized program because of the read/refill operation. For example, in a dual pulse embodiment of the single command shadow program operation, the operation may be suspended for a time interval after the lower page data of the (N+1)-th program loop word line is programmed to memory cells of the memory array during a first pulse to read the lower page data of the N-th program loop word line from the memory cells.

Continuing to refer to FIG. 9, the one-pass single command shadow program operation further comprises programming higher page data (e.g., TLC upper page data and extra page data) 940 to memory cells along the N-th word line. As shown, the higher page data for a TLC memory array can have eight possible states 942.

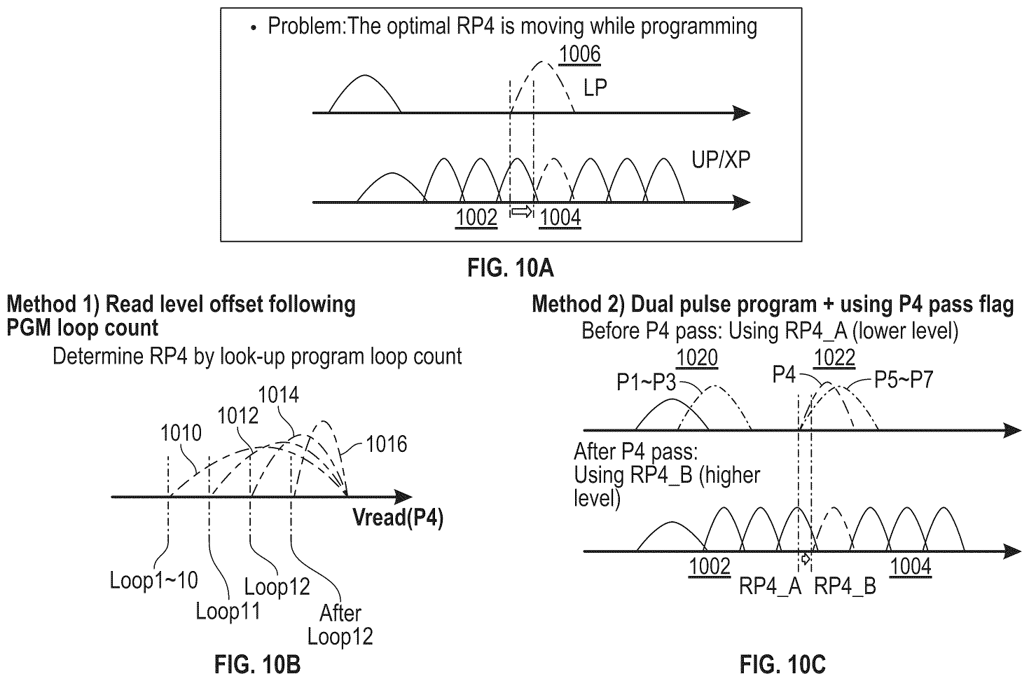

FIG. 10A-C are example diagrams showing threshold voltage distributions on select data word lines of a memory device during example operations including a single command shadow program operation of the memory device in accordance with examples as disclosed herein. FIG. 10A shows that the optimal P4 read level (RP4) moves, e.g., from V_{read(P4)} 1002 to V_{read(P4)} 1004, within the timeframe of the LP read operation 1006 during the single command shadow program. In one embodiment, a read level offset may be employed after a program loop count to mitigate the effects of the shift in the optimal RP4, as shown in FIG. 10B. For example, the RP4 read level offset may be determined by looking up a program loop count, e.g., Loop 1-10 1010. Loop 11 1012 Loop 12 1014, and after Loop 12 1016, as shown. In another embodiment, as shown in FIG. 10C, the single command shadow program may comprise a dual pulse program operation using a P4 pass flag. In a dual pulse configuration of the one-pass programming operation, the lower page data and higher page data (e.g., upper page data and extra page data) of the N-th word line may be programmed to the memory cells during a second pulse of the one-pass programming operation. For example, a first read level, RP4_A 1020 (e.g., a lower level read level), may be used before the P4 pass flag for RP4, while a second read level, RP4_B 1022 (e.g., a higher read level), may be used after the P4 pass flag.

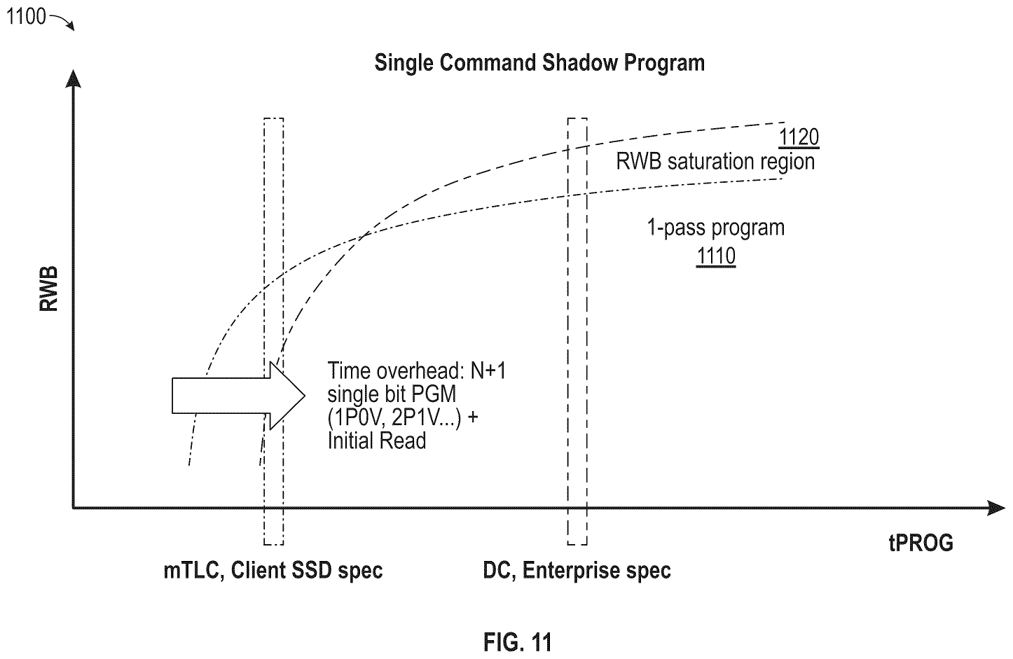

FIG. 11 is a graph 1100 showing different curves that represent a program time comparison of during example operations including a single command shadow program operation of the memory device in accordance with examples as disclosed herein. Graph 1100 shows read window budget (RWB) as a function of program time, t_{prog}, for a typical one-pass program 1110 and the single command showdown program 1120 as disclosed herein. As shown, the RWB (i.e., the minimum window that the process must be able to sustain in order to have a reliable reading) for the single command showdown program 1120 is maximized (e.g., for data center/enterprise specifications) despite the time overhead for the N+1 single bit program and the initial read. Further, a shallow trap reduction has been observed due to the time interval between the 1-bit LP program and the 3-bit LP+UP/XP program when the interval is maximized. Due to this effect, fewer electrons are injected into the N+1-th WL after the N-th WL program is completed.

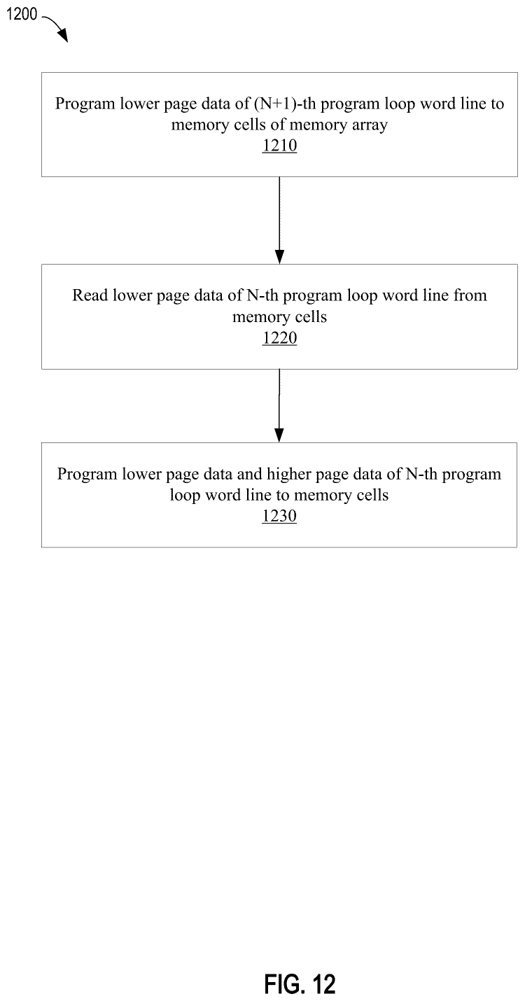

FIG. 12 is a flow diagram of an example method 1200 to perform a single command shadow program operation, in accordance with examples as disclosed herein. For example, a memory device may have a memory array and control logic (e.g., one or more memory controllers), coupled with the memory array, where the control logic is configured to perform to perform various operations in accordance with examples as described herein. As described above, the memory device, e.g., memory device 130, may include (e.g., on a same semiconductor die or within a same package) a local controller, e.g., local controller 135, which may execute operations on one or more memory cells of the memory device. The local controller may operate in conjunction with a memory system controller, e.g., memory system controller 115, which may both be referred to as memory controllers for simplicity. It is understood that while they may be different controllers, certain operations disclosed herein may be caused or performed by either or both memory controllers, unless otherwise specified. Further, in accordance with examples as disclosed herein, the memory device may comprise a memory array comprising multiple-level memory cells, and a controller, coupled with the memory array, is configured to program the multiple-level memory cells via a one-pass programming operation.

In accordance with examples as disclosed herein, single command shadow programming comprises a method for programming multiple-level memory cells (e.g., triple level memory cells or quad level memory cells) of a memory array by performing a one-pass programming operation. For example, the one-pass programming operation may be carried out by a single programming command.

In the one-pass programming operation at 1210, the controller may be configured to program lower page data to memory cells along an (N+1)-th word line. In some examples, the one-pass programming operation may comprise a dual pulse programming operation. For example, in a dual pulse configuration of the one-pass programming operation, the lower page data of the (N+1)-th program loop word line may be programmed to memory cells of the memory array during a first pulse.

In the one-pass programming operation at 1220, the controller may be further configured to read lower page data from memory cells along an N-th word line. For example, in a dual pulse configuration of the one-pass programming operation, where the lower page data of the (N+1)-th program loop word line is programmed to memory cells of the memory array during a first pulse, the operation may be suspended for a time interval to read the lower page data of the N-th program loop word line from the memory cells. Further, in some examples, the one-pass programming operation may comprise reading the lower page data of the N-th program loop word line from the memory cells using a first read level offset voltage prior to a program loop count threshold and reading the lower page data of the N-th program loop word line from the memory cells using a second read level offset voltage after the program loop count threshold. For example, a read level offset voltage may be determined based on a program loop count threshold, and the lower page data of the N-th program loop word line may be read from the memory cells based on the read level offset voltage. A threshold voltage for programming the lower page data of the (N+1)-th program loop word line to the memory cells may be lower than a read-level threshold voltage after the program loop count threshold, e.g., at least four program loops.

In the one-pass programming operation at 1230, the controller may be further configured to program higher page data (e.g., upper page data and extra page data) to memory cells along the N-th word line. For example, in a dual pulse configuration of the one-pass programming operation, the lower page data and higher page data (e.g., upper page data and extra page data) of the N-th program loop word line may be programmed to the memory cells during a second pulse of the one-pass programming operation.

Additional embodiments are included below.

(1) A memory device comprising:
a memory array comprising multiple-level memory cells; and
a controller, coupled with the memory array, the controller configured to program the multiple-level memory cells via a one-pass programming operation comprising operations to:
   program lower page data to memory cells along an (N+1)-th word line;
   read lower page data from memory cells along an N-th word line; and
   program higher page data to memory cells along the N-th word line.

(2) The memory device of (1), wherein the controller is further configured to carry out the one-pass programming operation by a single programming command.

(3) The memory device of any of (1)-(2), wherein programming the higher page data comprises programming upper page data and extra page data to the memory cells.

(4) The memory device of any of (1)-(3), wherein the controller is further configured to: determine a read level offset voltage based on a program loop count threshold; and read the lower page data from memory cells along the N-th word line based on the read level offset voltage.

(5) The memory device of any of (1)-(4), wherein the one-pass programming operation comprises a dual pulse programming operation.

(6) The memory device of (5), wherein the one-pass programming operation is suspended for a time interval to read the lower page data from memory cells along the N-th word line.

(7) The memory device of any of (1)-(6), wherein the controller is further configured to read the lower page data from memory cells along the N-th word line using a first read level offset voltage prior to a program loop count threshold and read the lower page data from memory cells along the N-th word line from the memory cells using a second read level offset voltage after the program loop count threshold.

(8) The memory device of (7), wherein a threshold voltage for programming the lower page data to memory cells along the (N+1)-th word line is lower than a read-level threshold voltage after the program loop count threshold.

(9) The memory device of any of (7)-(8), wherein the program loop count threshold is at least four program loops.

(10) The memory device of any of (1)-(9), wherein the controller is configured to program the multiple-level memory cells as triple level memory cells.

(11) The memory device of any of (1)-(10), wherein the controller is configured to program the multiple-level memory cells as quad level memory cells.

(12) A method for programming multiple-level memory cells of a memory array, the method comprising:
performing a one-pass programming operation by:
   programming lower page data to memory cells along an (N+1)-th word line;
   reading lower page data from memory cells along an N-th word line; and
   programming higher page data to memory cells along the N-th word line.

(13) The method of (12), wherein the one-pass programming operation is carried out by a single programming command.

(14) The method of any of (12)-(13), wherein programming the higher page data comprises programming upper page data and extra page data to the memory cells.

(15) The method of any of (12)-(14), further comprising:
determining a read level offset voltage based on a program loop count threshold; and
reading the lower page data from memory cells along the N-th word line based on the read level offset voltage.

(16) The method of any of (12)-(15), wherein the one-pass programming operation comprises a dual pulse programming operation.

(17) The method of (16), wherein the one-pass programming operation is suspended for a time interval to read the lower page data from memory cells along the N-th word line.

(18) The method of any of (12)-(17), wherein the one-pass programming operation comprises reading the lower page data from memory cells along the N-th word line using a first read level offset voltage prior to a program loop count threshold and reading the lower page data from memory cells along the N-th program loop word line using a second read level offset voltage after the program loop count threshold.

(19) The method of (18), wherein a threshold voltage for programming the lower page data to memory cells along the (N+1)-th word line is lower than a read-level threshold voltage after the program loop count threshold.

(20) The method of any of (18)-(19), wherein the program loop count threshold is at least four program loops.

(21) The method of any of (12)-(20), wherein the multiple-level memory cells are triple level memory cells.

(22) The method of any of (12)-(21), wherein the multiple-level memory cells are quad level memory cells.

(23) A non-transitory computer-readable medium having computer instructions stored thereon, which, when executed by controller circuitry of a memory device, cause the memory device to:
perform a one-pass programming operation for multiple-level memory cells of a memory array, the one-pass programming operation comprising operations to:
   program lower page data to memory cells along an (N+1)-th word line;
   read lower page data from memory cells along an N-th word line; and
   program lower page data and higher page data to memory cells along the N-th word line.

(24) The computer-readable medium of (23), wherein the instructions further cause the memory device to carry out the one-pass programming operation by a single programming command.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
a memory array comprising multiple-level memory cells; and
a controller, coupled with the memory array, the controller configured to program the multiple-level memory cells via a one-pass programming operation comprising operations to:
program lower page data to memory cells along an (N+1)-th word line;
read lower page data from memory cells along an N-th word line; and
program higher page data to memory cells along the N-th word line.

2. The memory device of claim 1, wherein the controller is further configured to carry out the one-pass programming operation by a single programming command.

3. The memory device of claim 1, wherein programming the higher page data comprises programming upper page data and extra page data to the memory cells.

4. The memory device of claim 1, wherein the controller is further configured to:
determine a read level offset voltage based on a program loop count threshold; and
read the lower page data from memory cells along the N-th word line based on the read level offset voltage.

5. The memory device of claim 1, wherein the one-pass programming operation comprises a dual pulse programming operation.

6. The memory device of claim 5, wherein the one-pass programming operation is suspended for a time interval to read the lower page data from memory cells along the N-th word line.

7. The memory device of claim 1, wherein the controller is further configured to read the lower page data from memory cells along the N-th word line using a first read level offset voltage prior to a program loop count threshold and read the lower page data from memory cells along the N-th word line from the memory cells using a second read level offset voltage after the program loop count threshold.

8. The memory device of claim 7, wherein a threshold voltage for programming the lower page data to memory cells along the (N+1)-th word line is lower than a read-level threshold voltage after the program loop count threshold.

9. The memory device of claim 7, wherein the program loop count threshold is at least four program loops.

10. The memory device of claim 1, wherein the controller is configured to program the multiple-level memory cells as triple level memory cells.

11. The memory device of claim 1, wherein the controller is configured to program the multiple-level memory cells as quad level memory cells.

12. A method for programming multiple-level memory cells of a memory array, the method comprising:
performing a one-pass programming operation by:
programming lower page data to memory cells along an (N+1)-th word line;
reading lower page data from memory cells along an N-th word line; and
programming higher page data to memory cells along the N-th word line.

13. The method of claim 12, wherein the one-pass programming operation is carried out by a single programming command.

14. The method of claim 12, wherein programming the higher page data comprises programming upper page data and extra page data to the memory cells.

15. The method of claim 12, further comprising:
determining a read level offset voltage based on a program loop count threshold; and
reading the lower page data from memory cells along the N-th word line based on the read level offset voltage.

16. The method of claim 12, wherein the one-pass programming operation comprises a dual pulse programming operation.

17. The method of claim 16, wherein the one-pass programming operation is suspended for a time interval to read the lower page data from memory cells along the N-th word line.

18. The method of claim 12, wherein the one-pass programming operation comprises reading the lower page data from memory cells along the N-th word line using a first read level offset voltage prior to a program loop count threshold and reading the lower page data from memory cells along the N-th program loop word line using a second read level offset voltage after the program loop count threshold.

19. The method of claim 18, wherein a threshold voltage for programming the lower page data to memory cells along the (N+1)-th word line is lower than a read-level threshold voltage after the program loop count threshold.

20. The method of claim 18, wherein the program loop count threshold is at least four program loops.

21. The method of claim 12, wherein the multiple-level memory cells are triple level memory cells.

22. The method of claim 12, wherein the multiple-level memory cells are quad level memory cells.

23. A non-transitory computer-readable medium having computer instructions stored thereon, which, when executed by controller circuitry of a memory device, cause the memory device to:
perform a one-pass programming operation for multiple-level memory cells of a memory array, the one-pass programming operation comprising operations to:
program lower page data to memory cells along an (N+1)-th word line;
read lower page data from memory cells along an N-th word line; and
program lower page data and higher page data to memory cells along the N-th word line.

24. The computer-readable medium of claim 23, wherein the instructions further cause the memory device to carry out the one-pass programming operation by a single programming command.
